(19) United States
(12) Patent Application Publication
(10) Pub. No.: US 2025/0203920 A1
(43) Pub. Date: Jun. 19, 2025

(54) SEMICONDUCTOR DEVICE AND METHOD FOR MANUFACTURING SEMICONDUCTOR DEVICE

(71) Applicant: Sony Semiconductor Solutions Corporation, Kanagawa (JP)

(72) Inventor: Kenichi Ookubo, Kanagawa (JP)

(21) Appl. No.: 18/843,391

(22) PCT Filed: Jan. 18, 2023
(86) PCT No.: PCT/JP23/01292

§ 371 Date: Sep. 3, 2024

(30) Foreign Application Priority Data
Mar. 10, 2022 (JP) 2022-036969

(51) Int. Cl. H10D 30/65; H10D 30/01; H10D 62/13; H10D 62/80; H10D 62/83; H10D 62/832; H10D 62/85; H10D 62/852

(52) U.S. Cl. CPC H10D 30/65; H10D 30/0281; H10D 62/157; H10D 62/8303; H10D 62/8325; H10D 62/8503; H10D 62/852; H10D 62/875

(57) ABSTRACT

Semiconductor devices with improved withstand voltage performance are disclosed. In one example, a semiconductor device includes a source region of a first conductivity type which includes a first semiconductor material; a channel region of a second conductivity type which is adjacent to the source region and includes the first semiconductor material; a first drain region of the second conductivity type which is adjacent to the channel region and including a second semiconductor material having a band gap wider than a band gap of the first semiconductor material; and a second drain region of the first conductivity type that is adjacent to the first drain region and includes the second semiconductor material.

### TECHNICAL FIELD

The present disclosure relates to a semiconductor device and a manufacturing method of the semiconductor device.

### BACKGROUND ART

In recent years, in order to cope with more various applications, there is an increasing demand for a high withstand voltage transistor capable of handling a large current.

For example, Patent Document 1 below discloses a field effect transistor in which a drift layer is formed between a channel and a drain. The field effect transistor disclosed in Patent Document 1 can suppress electric field concentration in the drift layer depleted by voltage application to the drain, and thus can achieve high withstand voltage performance.

### CITATION LIST

### Patent Document

Patent Document 1: Japanese Patent Application Laid-Open No. 2010-258328

### SUMMARY OF THE INVENTION

### Problems to be Solved by the Invention

However, a withstand voltage performance of the field effect transistor disclosed in Patent Document 1 depends on a length of the drift layer formed between the channel and the drain. Therefore, it is difficult to downsize the field effect transistor disclosed in Patent Document 1 while securing desired withstand voltage performance.

Therefore, the present disclosure proposes a novel and improved semiconductor device capable of improving withstand voltage performance with a smaller structure, and a method for manufacturing the semiconductor device.

### Solutions to Problems

According to the present disclosure, there is provided a semiconductor device, including: a source region of a first conductivity type which includes a first semiconductor material; a channel region of a second conductivity type which is adjacent to the source region and includes the first semiconductor material; a first drain region of the second conductivity type which is adjacent to the channel region and including a second semiconductor material having a band gap wider than a band gap of the first semiconductor material; and a second drain region of the first conductivity type that is adjacent to the first drain region and includes the second semiconductor material.

Also, according to the present disclosure, there is provided a method for manufacturing a semiconductor device, the method including: forming a drain region by replacing a part of a first semiconductor layer including a first semiconductor material with a second semiconductor material having a band gap wider than a band gap of the first semiconductor material; forming a gate electrode on the first semiconductor layer adjacent to the drain region through an insulating film; and forming a source region in the first semiconductor material layer adjacent to the region where the gate electrode is formed.

Furthermore, according to the present disclosure, there is provided a method for manufacturing a semiconductor device including: forming a gate electrode on a first semiconductor layer including a first semiconductor material through an insulating film; forming a drain region by replacing a part of the first semiconductor layer adjacent to a region where the gate electrode is formed with a second semiconductor material having a band gap wider than a band gap of the first semiconductor material; and forming a source region in the first semiconductor material layer adjacent to the region where the gate electrode is formed.

### BRIEF DESCRIPTION OF DRAWINGS

FIG. 1 is a longitudinal sectional view illustrating a configuration of a semiconductor device according to an embodiment of the present disclosure.

FIG. 2A is a longitudinal sectional view illustrating a step of a first method for manufacturing the semiconductor device.

FIG. 2B is a longitudinal sectional view illustrating a step of the first method for manufacturing the semiconductor device.

FIG. 2C is a longitudinal sectional view illustrating a step of the first method for manufacturing the semiconductor device.

FIG. 2D is a longitudinal sectional view illustrating a step of the first method for manufacturing the semiconductor device.

FIG. 2E is a longitudinal sectional view illustrating a step of the first method for manufacturing the semiconductor device.

FIG. 3A is a longitudinal sectional view illustrating a step of a second method for manufacturing the semiconductor device.

FIG. 3B is a longitudinal sectional view illustrating a step of the second method for manufacturing the semiconductor device.

FIG. 3C is a longitudinal sectional view illustrating a step of the second method for manufacturing the semiconductor device.

FIG. 3D is a longitudinal sectional view illustrating a step of the second method for manufacturing the semiconductor device.

FIG. 3E is a longitudinal sectional view illustrating a step of the second method for manufacturing the semiconductor device.

FIG. 4 is a side view illustrating a configuration of a semiconductor device according to a first modification.

FIG. 5 is a longitudinal sectional view illustrating a configuration of a semiconductor device according to a second modification.

FIG. 6 is a longitudinal sectional view illustrating a configuration of a semiconductor device according to a third modification.

FIG. 7 is a side view illustrating a configuration of a semiconductor device according to a fourth modification.

FIG. 8 is a longitudinal sectional view illustrating a configuration of a semiconductor device according to a fifth modification.

### MODE FOR CARRYING OUT THE INVENTION

Hereinafter, preferred embodiments of the present disclosure will be described in detail with reference to the accompanying drawings. Note that, in the present specification and drawings, components having substantially the same functional configuration are denoted by the same reference signs, and redundant description is omitted.

Note that description will be made in the following order.
1. Configuration example
2. Manufacturing method
2.1. First manufacturing method
2.2. Second manufacturing method
3. Modifications

### 1. Configuration

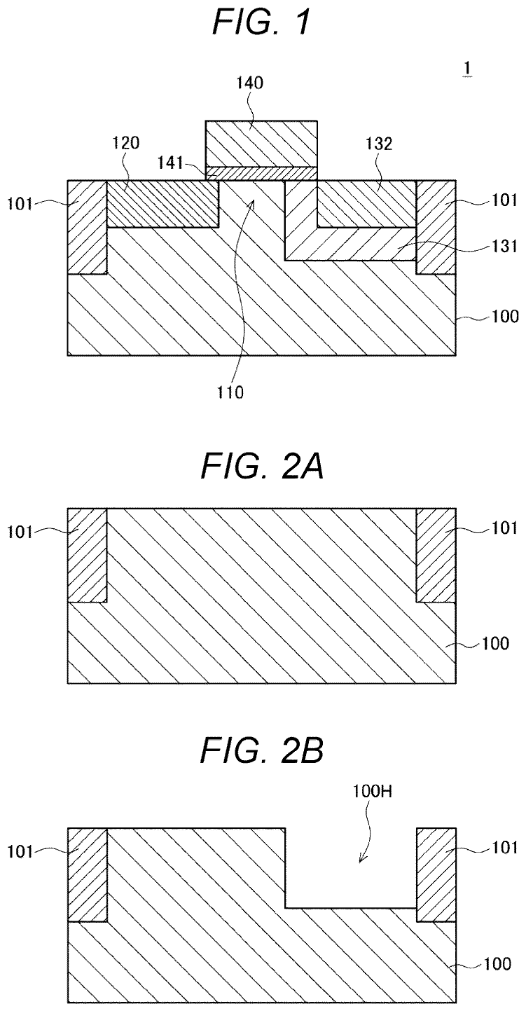

First, a configuration of a semiconductor device according to one embodiment of the present disclosure will be described with reference to FIG. 1. FIG. 1 is a longitudinal sectional view illustrating a configuration of a semiconductor device 1 according to the present embodiment.

As illustrated in FIG. 1, the semiconductor device 1 according to the present embodiment includes, for example, a semiconductor layer 100, a channel region 110, a source region 120, a first drain region 131, a second drain region 132, an element isolation layer 101, a gate insulating film 141, and a gate electrode 140.

In the semiconductor device 1 according to the present embodiment, the channel region 110 and the source region 120 include a first semiconductor material, and the first drain region 131 and the second drain region 132 include a second semiconductor material having a wider band gap than the first semiconductor material. Specifically, in a case where the first semiconductor material is Si (silicon), the second semiconductor material is SiC, GaN, AlN, InN, GaAs, diamond, ZnO, or AlGaN. More specifically, in a case where the first semiconductor material is Si, the second semiconductor material may be SiC.

The second semiconductor material has a wider band gap than the first semiconductor material. Therefore, a dielectric breakdown electric field of the second semiconductor material is higher than a dielectric breakdown electric field of the first semiconductor material. Therefore, the semiconductor device 1 can ensure high withstand voltage performance even in a case where a thickness of a depletion layer is small by forming the depletion layer in the first drain region 131 and the second drain region 132 including the second semiconductor material.

The semiconductor layer 100 is a layer including the first semiconductor material. In the semiconductor layer 100, the channel region 110 and the source region 120 are formed by introducing a conductivity type impurity, and the first drain region 131 and the second drain region 132 including the second semiconductor material are embedded. For example, the semiconductor layer 100 may be a Si layer provided on various substrates, or may be a Si substrate.

The element isolation layer 101 includes an inorganic insulating material, and is provided to extend inside the semiconductor layer 100, thereby electrically insulating the semiconductor device 1 from other elements and the like. Specifically, the element isolation layer 101 may be provided by embedding an inorganic insulating material in an opening formed by removing a part of the semiconductor layer 100. For example, the element isolation layer 101 may include silicon oxide (SiOₓ), silicon nitride (SiNₓ), silicon oxynitride (SiON), or the like.

The source region 120 is a region of a first conductivity type (for example, N type) provided in the semiconductor layer 100. For example, the source region 120 may be provided by ion-implanting first conductivity type impurities (phosphorus (P) or arsenic (As)) into the semiconductor layer 100 including the first semiconductor material.

The channel region 110 is a region of the second conductivity type (for example, P-type) provided in the semiconductor layer 100, and is provided adjacent to the source region 120. The channel region 110 may be provided by ion-implanting second conductivity type impurities (boron (B) or aluminum (Al)) into the semiconductor layer 100 including the first semiconductor material. Note that, in a case where the semiconductor layer 100 is a Si layer or a Si substrate of the second conductivity type (for example, P type), the channel region 110 may be provided as a region between the source region 120 and the first drain region 131.

The first drain region 131 is a second conductivity type (for example, P-type) region including the second semiconductor material, and is provided adjacent to the channel region 110. For example, the first drain region 131 may be provided by introducing a second conductivity type impurity (boron (B) or aluminum (Al)) into the second semiconductor material embedded in the semiconductor layer 100.

The second drain region 132 is a region of a first conductivity type (for example, N type) including a second semiconductor material, and is provided adjacent to the first drain region 131. Furthermore, the second drain region 132 is provided so as to be adjacent to the channel region 110 through the first drain region 131. For example, the second drain region 132 may be provided by introducing a first conductivity type impurity (phosphorus (P) or arsenic (As)) into a part of the first drain region 131 including the second semiconductor material. According to this, in the semiconductor device 1, when a high voltage is applied to the drain (second drain region 132), the depletion layer can be formed from the second drain region 132 toward the first drain region 131, so that a high-resistance withstand voltage region can be formed between the channel region 110 and the second drain region 132.

The gate electrode 140 includes a conductive material, and is provided on the semiconductor layer 100 through the gate insulating film 141. Specifically, the gate electrode 140 may be provided on the channel region 110 through the gate insulating film 141. For example, the gate electrode 140 may include poly-Si, and the gate insulating film 141 may include silicon oxide (SiOₓ). According to this, in the semiconductor device 1, since a metal-insulator-semiconductor (MIS) gate structure can be formed in the gate electrode 140, the gate insulating film 141, and the channel region 110, conduction of the channel region 110 can be controlled by applying a voltage to the gate electrode 140.

In the semiconductor device 1 according to the present embodiment, the depletion layer is formed from the second drain region 132 toward the first drain region 131 when a high voltage is applied to the drain (second drain region 132). Since the first drain region 131 and the second drain region 132 include the second semiconductor material having a higher dielectric withstand electric field than the first semiconductor material, the depletion layer formed in the first drain region 131 can exhibit higher withstand voltage even with a small width. Therefore, the semiconductor device 1 can ensure sufficient withstand voltage performance even if the semiconductor device 1 is smaller. According to this, the semiconductor device 1 can suppress destruction of the semiconductor device 1 in a case where a high voltage is applied to the drain (second drain region 132) by electro-static discharge (ESD) or the like.

In addition, in the semiconductor device 1, since the width of the depletion layer formed in the first drain region 131 is small, a sufficient depletion layer can be formed even in a case where the concentration of the conductivity type impurity in the first drain region 131 and the second drain region 132 is high. Therefore, since the semiconductor device 1 can increase the concentration of the conductivity type impurity in the first drain region 131 and the second drain region 132, an electrical resistance of the first drain region 131 and the second drain region 132 can be reduced. Therefore, the semiconductor device 1 can further reduce the on-resistance.

### 2. Manufacturing Method

### (2.1. First Manufacturing Method)

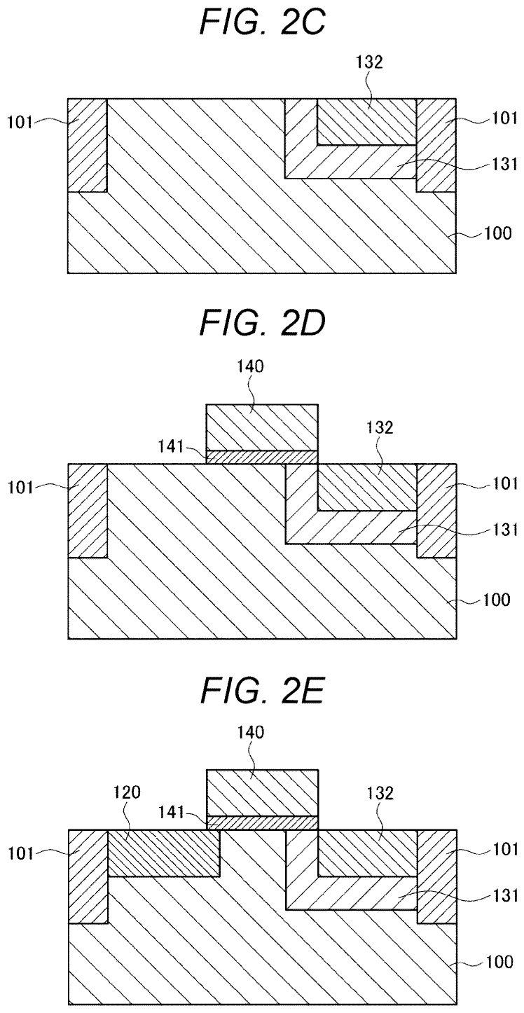

Next, a first manufacturing method of the semiconductor device 1 according to the present embodiment will be described with reference to FIGS. 2A to 2E. FIGS. 2A to 2E are longitudinal sectional views illustrating one step of the first manufacturing method of the semiconductor device 1. FIGS. 2A to 2E illustrate a cross section of the semiconductor device 1 cut in the thickness direction of the semiconductor layer 100.

First, as shown in FIG. 2A, a second conductivity type (for example, P type) Si layer is formed as semiconductor layer 100, and the element isolation layer 101 is formed in semiconductor layer 100. Specifically, in the semiconductor layer 100, an opening is formed so as to surround an entire periphery of a region where the semiconductor device 1 is formed, and the element isolation layer 101 is formed by filling the formed opening with SiOₓ.

Next, as illustrated in FIG. 2B, a part of the semiconductor layer 100 in the region surrounded by the element isolation layer 101 is removed by etching to form an opening 100H.

Thereafter, as illustrated in FIG. 2C, the first drain region 131 and the second drain region 132 are formed so as to embed the opening 100H. Specifically, first, SiC of the second conductivity type (for example, P-type) is epitaxially grown inside the opening 100H to form the second drain region 132. Subsequently, a first conductivity type impurity (for example, boron (B) or aluminum (Al)) is ion-implanted into a partial region in an upper portion of the second drain region 132, thereby forming the first drain region 131. Note that a surface of the semiconductor layer 100 after the formation of the first drain region 131 and the second drain region 132 may be planarized using chemical mechanical polishing (CMP) or the like.

Subsequently, as illustrated in FIG. 2D, the gate insulating film 141 and the gate electrode 140 are formed. Specifically, the gate insulating film 141 is an SiOₓ film formed by thermally oxidizing the surface of the semiconductor layer 100. After the surface of the semiconductor layer 100 is thermally oxidized, poly-Si is deposited on the gate insulating film 141, and the deposited poly-Si is patterned to form the gate electrode 140.

Thereafter, as illustrated in FIG. 2E, the source region 120 is formed in the semiconductor layer 100 on an opposite side of the first drain region 131 across the gate electrode 140. Specifically, the source region 120 is formed by ion-implanting a first conductivity type impurity (for example, phosphorus (P) or arsenic (As)) into the semiconductor layer 100 on the opposite side of the first drain region 131 across the gate electrode 140.

Through the above steps, the semiconductor device 1 according to the present embodiment is manufactured. In the first manufacturing method, the semiconductor device 1 can be manufactured by forming the gate electrode 140 after forming the first drain region 131 and the second drain region 132.

### (2.2. Second Manufacturing Method)

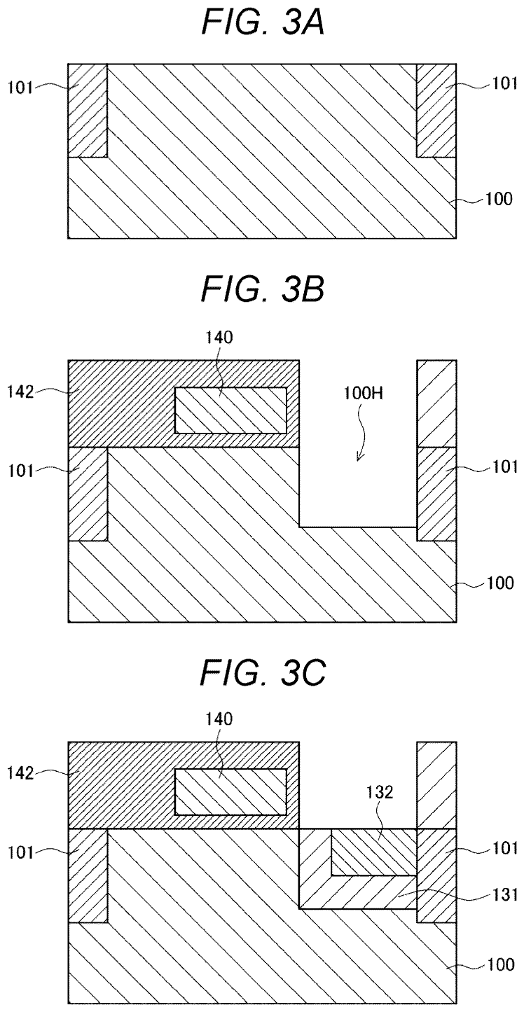

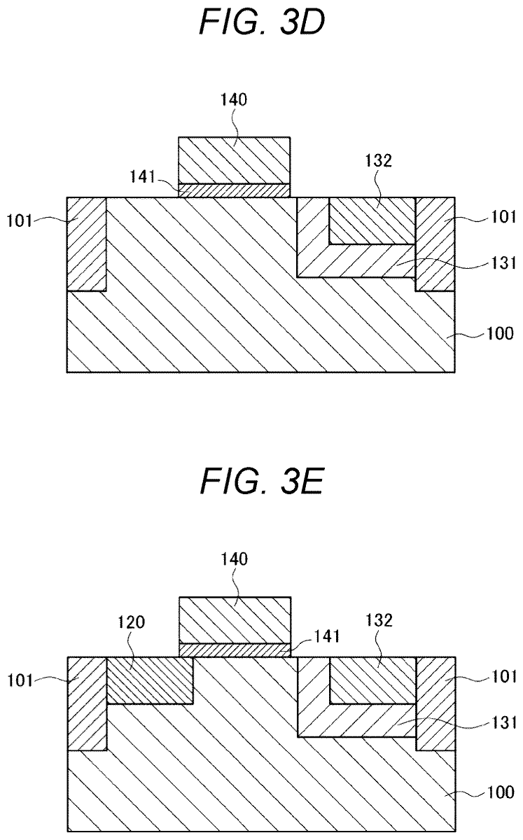

Next, a second manufacturing method of the semiconductor device 1 according to the present embodiment will be described with reference to FIGS. 3A to 3E. FIGS. 3A to 3E are longitudinal sectional views illustrating one step of the second manufacturing method of the semiconductor device 1. FIGS. 3A to 3E illustrate a cross section of the semiconductor device 1 cut in the thickness direction of the semiconductor layer 100.

First, as shown in FIG. 3A, a second conductivity type (for example, P type) Si layer is formed as the semiconductor layer 100, and the element isolation layer 101 is formed in semiconductor layer 100. Specifically, in the semiconductor layer 100, an opening is formed so as to surround the entire periphery of a region where the semiconductor device 1 is formed, and the element isolation layer 101 is formed by filling the formed opening with SiOₓ.

Next, as illustrated in FIG. 3B, after the gate electrode 140 and the insulating layer 142 are formed on the semiconductor layer 100, the opening 100H that digs the insulating layer 142 and the semiconductor layer 100 is formed. Specifically, first, poly-Si is deposited on the semiconductor layer 100 whose surface is thermally oxidized, and the deposited poly-Si is patterned to form the gate electrode 140. Next, SiOₓ is deposited so as to cover the gate electrode 140 using chemical vapor deposition (CVD), thereby forming the insulating layer 142. Subsequently, the insulating layer 142 in the region surrounded by the element isolation layer 101 and a part of the semiconductor layer 100 are removed by etching to form the opening 100H.

Thereafter, as illustrated in FIG. 3C, the first drain region 131 and the second drain region 132 are formed so as to embed the opening 100H. Specifically, first, SiC of the second conductivity type (for example, P-type) is epitaxially grown inside the opening 100H to form the second drain region 132. Subsequently, a first conductivity type impurity (for example, boron (B) or aluminum (Al)) is ion-implanted into a partial region in an upper portion of the second drain region 132, thereby forming the first drain region 131.

Subsequently, as illustrated in FIG. 3D, the insulating layer 142 deposited on the semiconductor layer 100 is removed by etching or the like. As a result, the SiOₓ layer remaining between the gate electrode 140 and the semiconductor layer 100 becomes the gate insulating film 141.

Thereafter, as illustrated in FIG. 3E, the source region 120 is formed in the semiconductor layer 100 on the opposite side of the first drain region 131 across the gate electrode 140. Specifically, the source region 120 is formed by ion-implanting a first conductivity type impurity (for example, phosphorus (P) or arsenic (As)) into the semiconductor layer 100 on the opposite side of the first drain region 131 across the gate electrode 140.

Through the above steps, the semiconductor device 1 according to the present embodiment is manufactured. In the second manufacturing method, the semiconductor device 1 can be manufactured by forming the first drain region 131 and the second drain region 132 after forming the gate electrode 140.

Note that, in the first manufacturing method and the second manufacturing method, the first drain region 131 is formed by introducing the first conductivity type impurity into the second drain region 132, but the present embodiment is not limited to such an example.

For example, the first drain region 131 may be formed by further epitaxially growing the SiC of the first conductivity type on the second drain region 132 after forming the second drain region 132 inside the opening 100H. Specifically, the second drain region 132 may be formed by uniformly epitaxially growing SiC of the second conductivity type on a side surface and a bottom surface of the opening 100H. Alternatively, the first drain region 131 may be formed by epitaxially growing the SiC of the first conductivity type so as to embed the opening 100H in which the second drain region 132 is formed.

### 3. Modifications

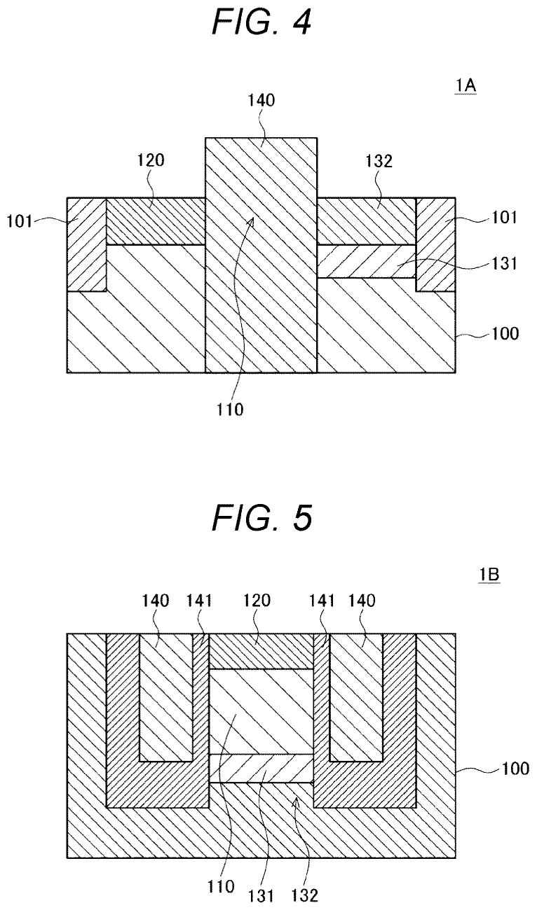

Next, first to fifth modifications of the semiconductor device 1 according to the present embodiment will be described with reference to FIGS. 4 to 8.

### (First Modification)

FIG. 4 is a side view illustrating a configuration of a semiconductor device 1A according to a first modification. As illustrated in FIG. 4, the semiconductor device 1A may be provided as a fin field-effect transistor (FinFET).

Specifically, the semiconductor layer 100 provided with a source region 120, a channel region 110, a first drain region 131, and a second drain region 132 is provided so as to protrude in a fin shape so as to expose the cross section illustrated in FIG. 1 to a side surface. The gate electrode 140 is provided across the semiconductor layer 100 protruding in a fin shape, so that the channel region 110 can be surrounded by three surfaces of an upper surface and both side surfaces through a gate insulating film (not illustrated). According to this, since the semiconductor device 1A can increase an effective channel length by forming a multi-gate structure, a short channel effect can be suppressed.

### (Second Modification)

FIG. 5 is a longitudinal sectional view illustrating a configuration of a semiconductor device 1B according to a second modification. As illustrated in FIG. 5, the semiconductor device 1B may be provided as a vertical gate transistor in which a gate electrode 140 is embedded in a semiconductor layer 100.

In the second modification, the semiconductor layer 100 is provided as a layer including a second semiconductor material of a first conductivity type (for example, N type). Therefore, the semiconductor layer 100 can function as a second drain region 132. Furthermore, in the semiconductor layer 100, a first drain region 131, a channel region 110, and a source region 120 are provided in a thickness direction of the semiconductor layer 100.

The first drain region 131 is formed by converting the semiconductor layer 100 including the second semiconductor material of a first conductivity type (for example, N type) into a second conductivity type (for example, P type). On the other hand, the channel region 110 and the source region 120 include the first semiconductor material embedded in the semiconductor layer 100. Specifically, the channel region 110 includes a first semiconductor material of the second conductivity type (for example, P type), and the source region 120 includes a first semiconductor material of the first conductivity type (for example, N type). As a result, in the semiconductor layer 100, the source region 120, the channel region 110, the first drain region 131, and the second drain region 132 are sequentially stacked in the thickness direction of the semiconductor layer 100.

The gate electrode 140 is provided by digging the semiconductor layer 100 in the thickness direction in a region adjacent to a side surface of a laminated structure of the source region 120, the channel region 110, the first drain region 131, and the second drain region 132. The gate electrode 140 includes a conductive material, and can form a MIS gate structure with the channel region 110 through the gate insulating film 141 including an inorganic insulating material. Accordingly, the gate electrode 140 extending inside the semiconductor layer 100 can control conduction of the channel region 110 through the gate insulating film 141.

In the semiconductor device 1B, when a high voltage is applied to the drain (second drain region 132), a depletion layer can be formed in the first drain region 131 including the second semiconductor material having a wider band gap than the first semiconductor material. Therefore, similarly to the semiconductor device 1 illustrated in FIG. 1, the semiconductor device 1B can ensure sufficient withstand voltage performance even with a smaller size.

### (Third Modification)

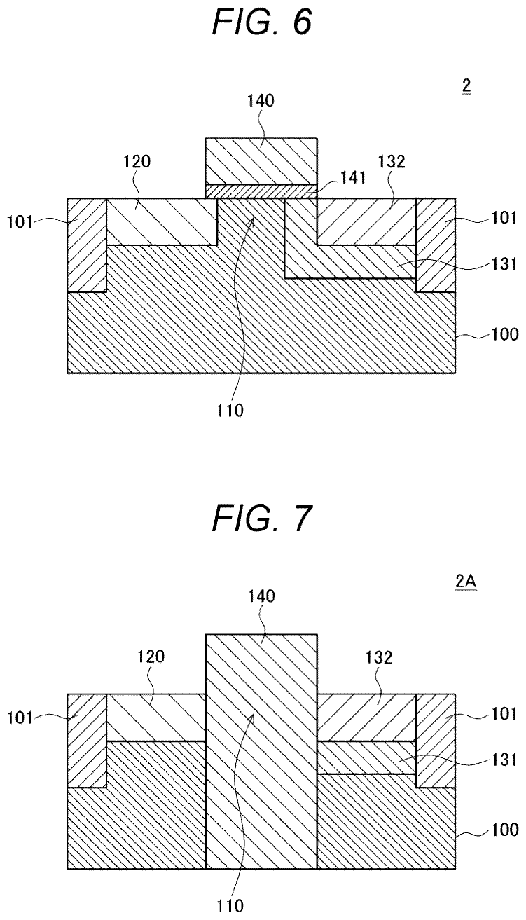

FIG. 6 is a longitudinal sectional view illustrating a configuration of a semiconductor device 2 according to a third modification. As illustrated in FIG. 6, the semiconductor device 2 is different from the semiconductor device 1 illustrated in FIG. 1 in that a polarity of the conductivity type impurity is opposite.

Specifically, a source region 120 is provided as a region of a second conductivity type (for example, P-type) including a first semiconductor material, and a channel region 110 is provided as a region of a first conductivity type (for example, N-type) including the first semiconductor material. In addition, a first drain region 131 is provided as a region of a first conductivity type (for example, N type) including a second semiconductor material, and a second drain region 132 is provided as a region of a second conductivity type (for example, P type) including the second semiconductor material.

In such a case, the semiconductor device 2 can function as a P-type channel transistor. Similarly to the semiconductor device 1 illustrated in FIG. 1, since the semiconductor device 2 can form a depletion layer in the first drain region 131 including the second semiconductor material having a wider band gap than the first semiconductor material, it is possible to secure sufficient withstand voltage performance even with a smaller size.

### (Fourth Modification)

FIG. 7 is a side view illustrating a configuration of a semiconductor device 2A according to a fourth modification. As illustrated in FIG. 7, the semiconductor device 2A is different from the semiconductor device 1A illustrated in FIG. 4 in that the polarity of the conductivity type impurity is opposite.

Specifically, a source region 120 is provided as a region of a second conductivity type (for example, P-type) including a first semiconductor material, and a channel region 110 is provided as a region of a first conductivity type (for example, N-type) including the first semiconductor material. In addition, a first drain region 131 is provided as a region of a first conductivity type (for example, N type) including a second semiconductor material, and a second drain region 132 is provided as a region of a second conductivity type (for example, P type) including the second semiconductor material.

In such a case, the semiconductor device 2A can function as a P-type channel FinFET. In the semiconductor device 2A, similarly to the semiconductor device 1A illustrated in FIG. 4, since the depletion layer can be formed in the first drain region 131 including the second semiconductor material having a wider band gap than the first semiconductor material, sufficient withstand voltage performance can be secured even with a smaller size.

### (Fifth Modification)

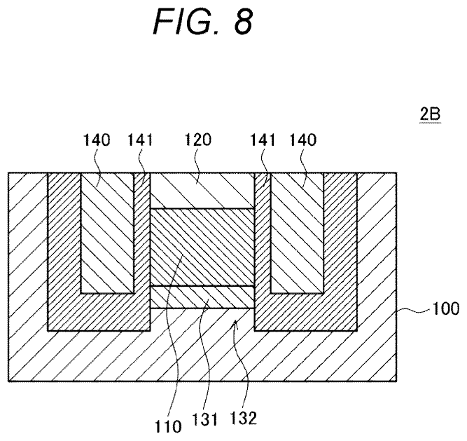

FIG. 8 is a longitudinal sectional view illustrating a configuration of a semiconductor device 2B according to a fifth modification. As illustrated in FIG. 8, the semiconductor device 2B is different from the semiconductor device 18 illustrated in FIG. 5 in that the polarity of the conductivity type impurity is opposite.

Specifically, a source region 120 is provided as a region of a second conductivity type (for example, P-type) including a first semiconductor material, and a channel region 110 is provided as a region of a first conductivity type (for example, N-type) including the first semiconductor material. In addition, a first drain region 131 is provided as a region of a first conductivity type (for example, N type) including a second semiconductor material, and a second drain region 132 is provided as a region of a second conductivity type (for example, P type) including the second semiconductor material.

In such a case, the semiconductor device 2B can function as a P-type channel vertical gate transistor. In the semiconductor device 2B, similarly to the semiconductor device 1B illustrated in FIG. 5, since the depletion layer can be formed in the first drain region 131 including the second semiconductor material having a wider band gap than the first semiconductor material, sufficient withstand voltage performance can be secured even with a smaller size.

The preferred embodiments of the present disclosure have been described above in detail with reference to the accompanying drawings, but the technical scope of the present disclosure is not limited to such examples. It is obvious that those with ordinary skill in the technical field of the present disclosure can conceive various alterations or corrections within the scope of the technical idea recited in the claims, and it is naturally understood that these alterations or corrections also fall within the technical scope of the present disclosure.

Furthermore, the effects described in the present specification are merely exemplary or illustrative, and not restrictive. That is, the technology according to the present disclosure can exhibit other effects apparent to those skilled in the art from the description of the present specification, in addition to the effects described above or instead of the effects described above.

Note that the following configurations also fall within the technological scope of the present disclosure.

(1)

A semiconductor device, including:
a source region of a first conductivity type which includes a first semiconductor material;
a channel region of a second conductivity type which is adjacent to the source region and includes the first semiconductor material;
a first drain region of the second conductivity type which is adjacent to the channel region and including a second semiconductor material having a band gap wider than a band gap of the first semiconductor material; and
a second drain region of the first conductivity type that is adjacent to the first drain region and includes the second semiconductor material.
   (2)

The semiconductor device according to the above (1), in which
the first semiconductor material is Si, and
the second semiconductor material is SiC, GaN, AlN, InN, GaAs, diamond, ZnO, or AlGaN.
   (3)

The semiconductor device according to the above (1) or (2), in which
the first conductivity type is one of an N-type and a P-type, and
the second conductivity type is the other of an N-type and a P-type different from the first conductivity type.
   (4)

The semiconductor device according to any one of the above (1) to (3), in which
the source region, the channel region, the first drain region, and the second drain region are provided adjacent to each other in an in-plane direction of a first semiconductor layer including the first semiconductor material.
   (5)

The semiconductor device according to the above (4), in which the first drain region and the second drain region are provided in a region in which a part of the first semiconductor layer is replaced with the second semiconductor material.

(6)

The semiconductor device according to the above (5), in which the second drain region is provided inside the first drain region.

(7)

The semiconductor device according to any one of the above (4) to (6), further including a gate electrode adjacent to the channel region through an insulating film.

(8)

The semiconductor device according to the above (7), in which
the first semiconductor layer is provided in a fin shape, and
the gate electrode is adjacent to the channel region by two or more surfaces.
   (9)

The semiconductor device according to any one of the above (1) to (3), in which the source region, the channel region, the first drain region, and the second drain region are provided adjacent to each other in a thickness direction of a second semiconductor layer including the second semiconductor material.

(10)

The semiconductor device according to the above (9), in which the source region and the channel region are provided in a region where a part of the second semiconductor layer is replaced with the first semiconductor material.

(11)

The semiconductor device according to the above (9) or (10), further including a gate electrode embedded in the second semiconductor layer,
in which the gate electrode is adjacent to the channel region through an insulating film.
   (12)

A method for manufacturing a semiconductor device, the method including:
forming a drain region by replacing a part of a first semiconductor layer including a first semiconductor material with a second semiconductor material having a band gap wider than a band gap of the first semiconductor material;
forming a gate electrode on the first semiconductor layer adjacent to the drain region through an insulating film; and
forming a source region in the first semiconductor layer adjacent to the region where the gate electrode is formed.
   (13)

A method for manufacturing a semiconductor device, the method including:
forming a gate electrode on a first semiconductor layer including a first semiconductor material through an insulating film;
forming a drain region by replacing a part of the first semiconductor layer adjacent to a region where the gate electrode is formed with a second semiconductor material having a band gap wider than a band gap of the first semiconductor material; and
forming a source region in the first semiconductor layer adjacent to the region where the gate electrode is formed.

### REFERENCE SIGNS LIST

1, 1A, 1B, 2, 2A, 2B Semiconductor device
100 Semiconductor layer
101 Element isolation layer
110 Channel region
120 Source region
131 First drain region
132 Second drain region
140 Gate electrode
141 Gate insulating film

1. A semiconductor device, comprising:
a source region of a first conductivity type which includes a first semiconductor material;
a channel region of a second conductivity type which is adjacent to the source region and includes the first semiconductor material;
a first drain region of the second conductivity type which is adjacent to the channel region and including a second semiconductor material having a band gap wider than a band gap of the first semiconductor material; and
a second drain region of the first conductivity type that is adjacent to the first drain region and includes the second semiconductor material.

2. The semiconductor device according to claim 1, wherein
the first semiconductor material is Si, and
the second semiconductor material is SiC, GaN, AlN, InN, GaAs, diamond, ZnO, or AlGaN.

3. The semiconductor device according to claim 1, wherein
the first conductivity type is one of an N-type and a P-type, and
the second conductivity type is the other of an N-type and a P-type different from the first conductivity type.

4. The semiconductor device according to claim 1, wherein
the source region, the channel region, the first drain region, and the second drain region are provided adjacent to each other in an in-plane direction of a first semiconductor layer including the first semiconductor material.

5. The semiconductor device according to claim 4, wherein
the first drain region and the second drain region are provided in a region in which a part of the first semiconductor layer is replaced with the second semiconductor material.

6. The semiconductor device according to claim 5, wherein
the second drain region is provided inside the first drain region.

7. The semiconductor device according to claim 4, further comprising a gate electrode adjacent to the channel region through an insulating film.

8. The semiconductor device according to claim 7, wherein
the first semiconductor layer is provided in a fin shape, and
the gate electrode is adjacent to the channel region by two or more surfaces.

9. The semiconductor device according to claim 1, wherein the source region, the channel region, the first drain region, and the second drain region are provided adjacent to each other in a thickness direction of a second semiconductor layer including the second semiconductor material.

10. The semiconductor device according to claim 9, wherein the source region and the channel region are provided in a region where a part of the second semiconductor layer is replaced with the first semiconductor material.

11. The semiconductor device according to claim 9, further comprising a gate electrode embedded in the second semiconductor layer,
wherein the gate electrode is adjacent to the channel region through an insulating film.

12. A method for manufacturing a semiconductor device, the method comprising:
forming a drain region by replacing a part of a first semiconductor layer including a first semiconductor material with a second semiconductor material having a band gap wider than a band gap of the first semiconductor material;
forming a gate electrode on the first semiconductor layer adjacent to the drain region through an insulating film; and
forming a source region in the first semiconductor layer adjacent to the region where the gate electrode is formed.

13. A method for manufacturing a semiconductor device, the method comprising:
forming a gate electrode on a first semiconductor layer including a first semiconductor material through an insulating film;
forming a drain region by replacing a part of the first semiconductor layer adjacent to a region where the gate electrode is formed with a second semiconductor material having a band gap wider than a band gap of the first semiconductor material; and
forming a source region in the first semiconductor layer adjacent to the region where the gate electrode is formed.
